(19) United States
(12) Patent Application Publication
(10) Pub. No.: US 2026/0068060 A1
(43) Pub. Date: Mar. 5, 2026

(54) Controlling Apparatus for Vehicle

(71) Applicant: HYUNDAI MOBIS CO., LTD., Seoul (KR)

(72) Inventors: Sung Hyun PARK, Yongin-si (KR); Hyun Seong LEE, Yongin-si (KR); Sun Jong OH, Yongin-si (KR); Byung Mo YU, Yongin-si (KR); Sung Bae JEON, Yongin-si (KR); Kyeong Jun LEE, Yongin-si (KR); In Gun KIM, Yongin-si (KR)

(73) Assignee: HYUNDAI MOBIS CO., LTD., Seoul (KR)

(21) Appl. No.: 19/214,733

(22) Filed: May 21, 2025

(30) Foreign Application Priority Data
Sep. 4, 2024 (KR) 10-2024-0119750

(51) Int. Cl. H05K 5/00; H05K 7/20

(52) U.S. Cl. CPC H05K 5/0056; H05K 7/20145; H05K 7/20418

(57) ABSTRACT

A controlling apparatus for a vehicle, comprising: a cover top disposed on an upper end of the controlling apparatus; a moisture blocking cover bolted to an upper portion of the cover top and primarily blocking moisture flowing inside from above the controlling apparatus; a main chassis disposed at a lower end of the cover top and formed to accommodate a PCB in the controlling apparatus; and a fan disposed on any one lateral surface of the main chassis and generating forcible convention in a first direction that is an opposite lateral direction, wherein the cover top has a drain groove having a moisture discharge path guiding moisture falling down to the PCB through the moisture blocking cover to a front and a rear of the controlling apparatus.

### CROSS-REFERENCE TO RELATED APPLICATION

This application claims the benefit of and priority to Korean Patent Application No. 2024-0119750, filed on Sep. 4, 2024, the entire disclosure(s) of which is hereby incorporated herein by reference in its entirety.

### TECHNICAL FIELD

The present disclosure relates to a controlling apparatus for a vehicle.

### BACKGROUND

The description of this part only provides the background information of the present disclosure without configuring the related art.

Vehicles are equipped with controllers that require various functions and performance. The controllers apply chipsets with large and small power consumption on the basis of the required performance. Since the higher the power consumption, the more heat the controllers generate, heat dissipation parts and a fan are used to maintain the temperature condition of chipsets. In particular, a fan that forcibly generates convection is necessarily applied to high-performance controllers.

A fan that is applied to a controller is applied outside or inside the controller and performs a heat dissipation function through forcible convection around a heat generation source. It is necessary to ensure a channel having an inlet and an outlet in order to maximize the effect of forcible convection by a fan applied to a controller. However, when an open shape such as a hole is formed at a controller to ensure a channel of a fan, there may be a problem in that moisture flows inside from the outside of the controller.

In particular, when a fan is applied to the upper end of a controller, there is a problem in that the controller is vulnerable to moisture falling from above the controller.

### SUMMARY

Accordingly, in order to solve these problems, a main object of the present disclosure is to prevent moisture from reaching a PCB in a controlling apparatus by blocking moisture flowing into the controlling apparatus.

Further, a main object of the present disclosure is to improve heat dissipation performance by increasing the flow speed of forcible convection by a fan using channel cross-sections formed between a moisture blocking cover disposed at the upper end of a controlling apparatus and heat dissipation fins

The objects of the present disclosure are not limited to the objects described above and other objects will be clearly understood by those skilled in the art from the following description.

### ADVANTAGEOUS EFFECTS

According to an embodiment, the controlling apparatus for a vehicle has an effect that it is possible to prevent moisture from reaching a PCB in the controlling apparatus by blocking moisture flowing into the controlling apparatus.

According to an embodiment, the controlling apparatus for a vehicle has an effect that it is possible to improve heat dissipation performance by increasing the flow speed of forcible convection by a fan using channel cross-sections formed between a moisture blocking cover disposed at the upper end of the controlling apparatus and heat dissipation fins.

### BRIEF DESCRIPTION OF THE DRAWINGS

FIG. 1 is a view showing the configuration of a controlling apparatus for a vehicle according to an embodiment of the present disclosure.

FIG. 2 is an exploded perspective view showing the configuration of the controlling apparatus for a vehicle according to an embodiment of the present disclosure.

FIG. 3 is a cross-sectional view taken along line A-A in FIG. 1.

FIG. 4 is a cross-sectional view taken along line B-B in FIG. 1.

FIG. 5 is a cross-sectional view showing a second moisture discharge path of the controlling apparatus for a vehicle according to an embodiment of the present disclosure.

### DETAILED DESCRIPTION

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, A, B, (a), (b), etc., are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

The following detailed description, together with the accompanying drawings, is intended to describe exemplary embodiments of the present disclosure, and is not intended to represent the only embodiments in which the present disclosure may be practiced.

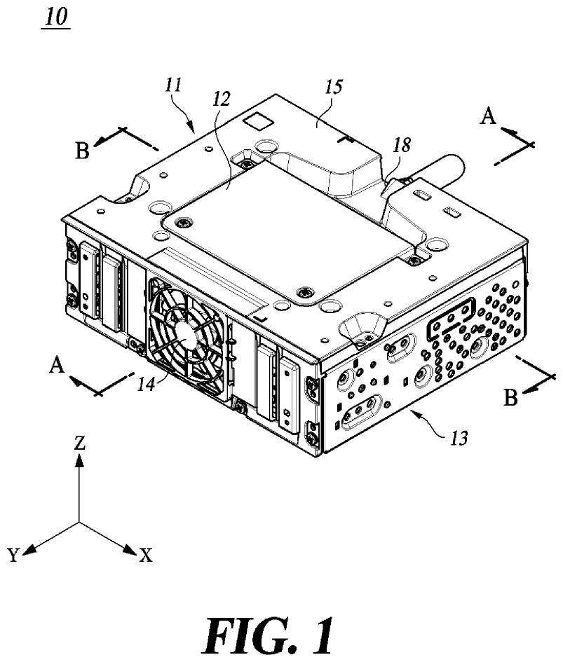

FIG. 1 is a view showing the configuration of a controlling apparatus for a vehicle according to an embodiment of the present disclosure.

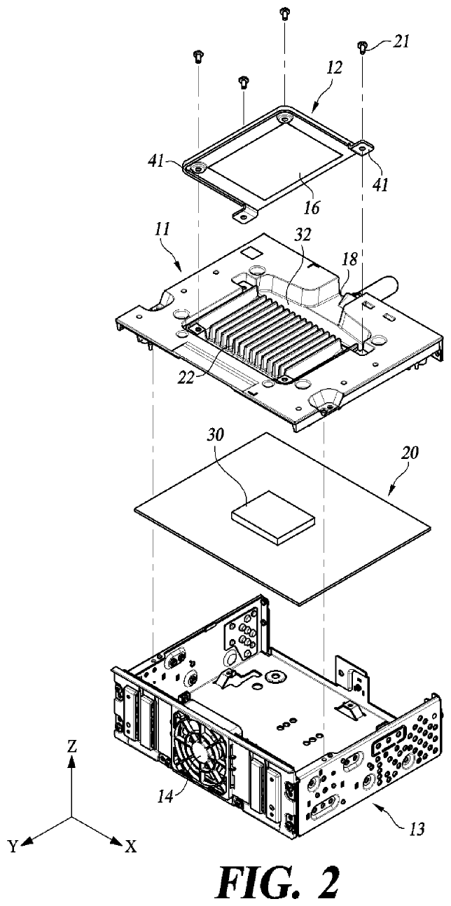

FIG. 2 is an exploded perspective view showing the configuration of the controlling apparatus for a vehicle according to an embodiment of the present disclosure.

Referring to FIG. 1 and FIG. 2, a controlling apparatus 10 for a vehicle according to an embodiment of the present disclosure includes some or all of a cover top 11, a moisture blocking cover 12, a main chassis 13, a Printed Circuit Board (PCB) 20, and a fan 14.

The cover top 11 is disposed on the uppermost end of the controlling apparatus 10 for a vehicle.

The cover top 11 is coupled to the upper end of the main chassis 13 to be described below.

The cover top 11 may be manufactured using an aluminum die-casting material. However, the material of the cover top 11 is not limited thereto. It is preferable that the cover top 11 is manufactured using a material with high heat dissipation performance to dissipate heat of the controlling apparatus 10.

The cover top 11 includes heat dissipation fins 22. The heat dissipation fins 22 are formed upward in a predetermined area of a drain groove 18. The heat dissipation fins 22 are formed in a direction parallel with a forcible convection direction by the fan 14 (y-axial direction in FIG. 1) and are arranged in parallel in an x-axial direction. Accordingly, the controlling apparatus 10 for a vehicle of the present disclosure can dissipate heat generated in the controlling apparatus 10 to the outside using the fan 14 and the heat dissipation fins 22.

The moisture blocking cover 12 is coupled to the upper portion of the cover top 11 using bolts 21. Since the moisture blocking cover 12 and the cover top 11 are coupled and fixed to each other, it is possible to prevent moisture falling from above from flowing into the controlling device 10.

The moisture blocking cover 12 can primarily block moisture falling from above and flowing into the controlling apparatus 10. The primarily blocked moisture can be discharged forward from the controlling apparatus 10 (in the y-axial direction in FIG. 1) or can be guided into the drain groove 18 and discharged rearward from the controlling apparatus 10 (in the (−)y-axial direction in FIG. 1).

A thermal interface material 16 may be disposed on the rear surface of the moisture blocking cover 12.

The thermal interface material 16, for example, may be any one of thermal grease, a thermal tape, a thermal pad, and a phase change material.

The moisture blocking cover 12 includes a plurality of fixing portions 17 for coupling to the upper end of a cover groove through the bolts 21. The plurality of fixing portions 17 may be embossed or may be formed in bracket shapes.

Masking may be applied to the edge area of the rear surface of the moisture blocking cover 12 where the thermal interface material 16 is not attached. For example, black masking may be applied to the edge area of the rear surface of the moisture blocking cover 12.

Various devices are mounted on the PCB 20. The PCB 20 that is applied to the controlling apparatus 10 for a vehicle controls an engine, a transmission, an Anti-lock Braking System (ABS), an airbag, a car body, an infotainment system, an autonomous driving, and the like. In particular, the advanced functions of vehicles require high-performance CPUs and GPUs.

A heat generation source 30 mounted on the PCB 20 according to an embodiment of the present disclosure may be a Central Processing Unit (CPU). For example, a CPU may be disposed in contact with or adjacent to the lower end of the drain groove 18 for effective heat dissipation.

The main chassis 13 is disposed at the lower end of the cover top 11. The main chassis 13 forms an outer case of the controlling apparatus 10 together with the cover top 11.

The main chassis 13 is formed to protect the PCB 20 accommodated in the controlling apparatus 10 from external shock.

The fan 14 may be disposed on any one lateral surface of the main chassis 13.

It is preferable that the fan 14 according to an embodiment of the present disclosure is disposed in the lateral direction of the main chassis 13. This is because when the fan 14 is disposed in an upward direction of the controlling apparatus 10, moisture falling from above and flowing into the controlling apparatus 10 can reach the inside of the controlling apparatus 10 through the fan 14.

The material of the main chassis 13, for example, may be Steel Electrolytic Cold Commercial (SECC) and a PC-ABS alloy. For example, a surface of the main chassis on which the fan 14 is disposed may be made of a PC-ABS alloy.

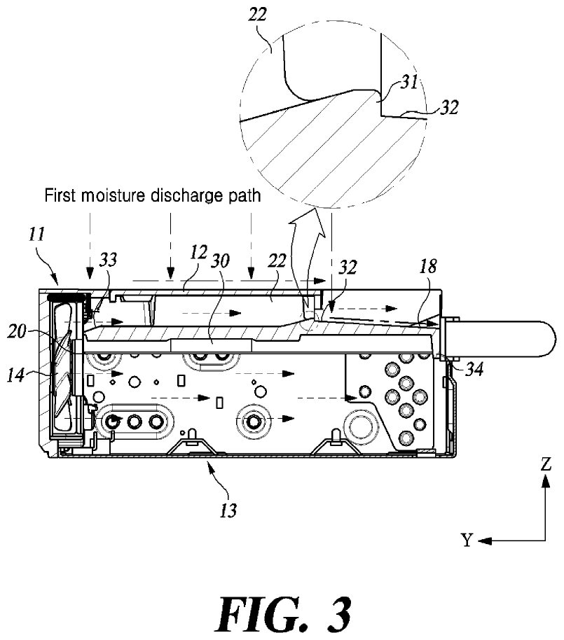

FIG. 3 is a cross-sectional view taken along line A-A in FIG. 1.

Referring to FIG. 1 to FIG. 3, the fan 14 according to an embodiment of the present disclosure can dissipate heat of the heat generation source 30 by generating forcible convection over and under the drain groove 18.

The fain 14 can generate forcible convection in a first direction ((−)y direction in FIG. 3) from any one surface of the main chassis 13.

The forcible convection generated from the fan 14 moves to the rear of the controlling apparatus 10 through the portions over and under the drain groove 18. The forcible convection passing through the portion over the drain groove 18 moves rearward through the spaces between the heat dissipation fins 22. Accordingly, heat generated from the heat generation source 30 mounted on the PCB 20 is conducted to an area in contact with the bottom surface of the drain groove 18 and is conducted to the moisture blocking cover 12 by the heat dissipation fins 22 formed in a predetermined area in the drain groove 18. In this case, the fan 14 can perform effective heat dissipation by generating forcible convection in the first direction to the heat that is conducted through the heat dissipation fins 22.

A side and another side of the drain groove 18 are open such that the forcible convection generated from the fan 14 moves from a second direction side that is the front of the controlling apparatus 10 to a first direction side that is the opposite direction to the first direction through the heat dissipation fins 22. In detail, an open hole corresponding to the size of the fan 14 may be formed on a side of the drain groove 18 adjacent to the fan 14.

The cover top 11 according to an embodiment of the present disclosure includes the drain groove 18.

The drain groove 18 according to an embodiment of the present disclosure is formed in a shape bending downward from the top surface 15 of the cover top 11.

The drain groove 18 has a moisture discharge path for guiding and discharging moisture falling from above the controlling apparatus 10 to the front and rear of the controlling apparatus 10.

The drain groove 18 includes some or all of a moisture anti-inflow step 31, a first slope 32, a second slope 33, and a bending portion 34.

The moisture anti-inflow step 31 forms a step by a predetermined height to prevent moisture flowing down from the moisture blocking cover 12 from flowing to the heat dissipation fins 22.

The first slope 32 has a downward slope such that moisture is guided and flows down in the first direction ((−)y-axial direction in FIG. 3) from the moisture anti-inflow step 31.

The second slope 33 has a downward slope such that moisture flows down to the outside from another end in the second direction (y-axial direction in FIG. 3) from the moisture anti-inflow step 31.

In this case, the downward slopes of the first slope 32 and the second slope 33 may be slopes that do not cause surface tension by moisture being accumulated on a plane. In other words, the first slope 32 and the second slope 33 may be tapered surfaces based on a predetermined slope to prevent accumulation of moisture.

The bending portion 34 is formed by bending downward from another end of the first slop 32 in the first direction. The bending portion 34 can protect the PCB 20 from moisture flowing inside from the rear.

Moisture flowing inside from above primarily reaches the moisture blocking cover 12 or the top surface 15 of the cover top 11 of the controlling apparatus 10 for a vehicle. Alternatively, moisture may directly fall and flow to the first slope 32 of the drain groove 18.

The controlling apparatus 10 for a vehicle according to an embodiment of the present disclosure includes a first moisture discharge path through which moisture falling to the moisture blocking cover 12 moves rearward (in the (−)y-axial direction in FIG. 3) and falls to the second slope 33 of the drain groove 18. The first moisture discharge path has a path through which moisture falling to the second slope 33 is discharged rearward by the second slope 33.

For example, moisture falling to the second slope 33 does not flow forward by forcible convection by the fan 14. However, moisture falling to the second slope 33 is prevented from flowing forward (in the y-axial direction in FIG. 3) by the moisture anti-inflow step 31 even if there is no forcible convection by the fan 14.

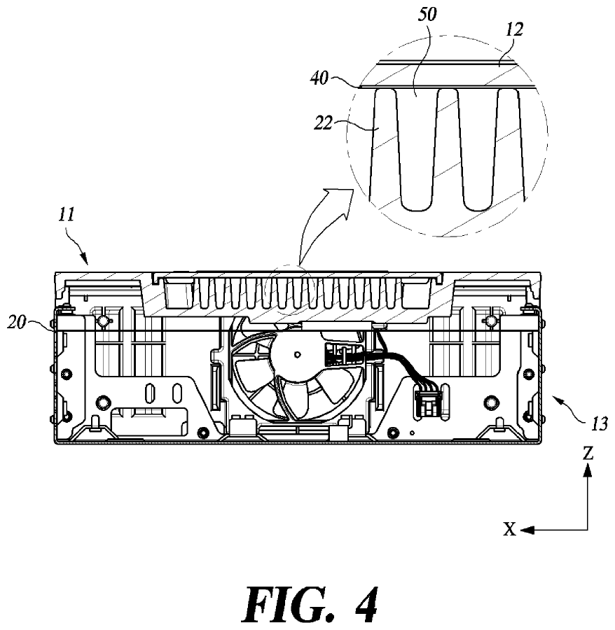

FIG. 4 is a cross-sectional view taken along line B-B in FIG. 1.

Referring to FIG. 1 to FIG. 4, when the moisture blocking cover 12 is coupled to the cover top 11, the thermal interface material 16 is disposed in contact with the heat dissipation fins 22. The thermal interface material 16 is disposed in contact with the heat dissipation fins 22 such that heat discharged from the heat generation source 30 can be dissipated upward from the moisture blocking cover 12.

A plurality of channel cross-sections 50 is formed between the heat dissipation fins 22 that are in contact with the thermal interface material 16. The plurality of formed channel cross-sections 50 can increase the flow speed of forcible convection generated from the fan 14. Accordingly, the plurality of channel cross-sections 50 formed between the moisture blocking cover 12 and the heat dissipation fins 22 can increase heat dissipation performance in comparison to when the moisture blocking cover 12 is not coupled to the cover top 11.

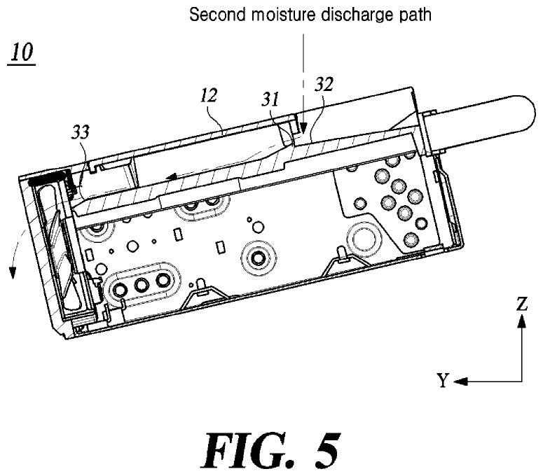

FIG. 5 is a cross-sectional view showing a second moisture discharge path of the controlling apparatus 10 for a vehicle according to an embodiment of the present disclosure.

Referring to FIG. 1 to FIG. 5, the controlling apparatus 10 for a vehicle according to an embodiment of the present disclosure has a moisture discharge path for discharging moisture flowing inside.

The moisture discharge path according to an embodiment guides moisture falling through the moisture blocking cover 12 to the front and rear of the controlling apparatus 10.

The moisture discharge path according to an embodiment includes the first moisture discharge path and the second moisture discharge path described above with reference to FIG. 3.

The first moisture discharge path refers to a path through which moisture falling from above the controlling apparatus 10 or moisture accumulating on the top surface 15 of the cover top 11 falls down to the rear of the controlling apparatus 10 along the moisture blocking cover 12 and is discharged rearward along the second slope 33.

On the other hand, the second moisture discharge path refers to a path through which moisture falls down to the rear of the controlling apparatus 10 along the moisture blocking cover 12 and is discharged to the front of the controlling apparatus 10 along the first slope 32.

The second moisture discharge path according to an embodiment of the present disclosure corresponds to the controlling apparatus 10 coupled at an angle forward in a vehicle or the controlling apparatus 10 when a vehicle enters a downward slope. Accordingly, moisture falling along the moisture blocking cover 12 may be guided to the first slope 32 and discharged to the front from the controlling apparatus 10 without being discharged through the second slope 33.

Moisture that is discharged to the front from the controlling apparatus 10 by the second moisture discharge path is discharged outside through the fan 14 after passing through the first slope 32.

Although exemplary embodiments of the present disclosure have been described for illustrative purposes, those skilled in the art will appreciate that various modifications, additions, and substitutions are possible, without departing from the idea and scope of the claimed disclosure. Therefore, exemplary embodiments of the present disclosure have been described for the sake of brevity and clarity. The scope of the technical idea of the present embodiments is not limited by the illustrations. Accordingly, one of ordinary skill would understand that the scope of the claimed disclosure is not to be limited by the above explicitly described embodiments but by the claims and equivalents thereof.

What is claimed is:

1. A controlling apparatus for a vehicle, comprising:
a cover top disposed on an upper end of the controlling apparatus;
a moisture blocking cover bolted to an upper portion of the cover top and primarily blocking moisture flowing inside from above the controlling apparatus;
a main chassis disposed at a lower end of the cover top and formed to accommodate a PCB in the controlling apparatus; and
a fan disposed on any one lateral surface of the main chassis and generating forcible convention in a first direction that is an opposite lateral direction,
wherein the cover top has a drain groove having a moisture discharge path guiding moisture falling down to the PCB through the moisture blocking cover to a front and a rear of the controlling apparatus.

2. The controlling apparatus of claim 1, wherein the drain groove includes:
heat dissipation fins arranged upward in a predetermined area;
a moisture anti-inflow step forming a step by a predetermined height to prevent moisture flowing down from the moisture blocking cover from flowing in a second direction that is an opposite direction to the first direction;
a first slope having a downward slope such that moisture is guided and flows down in the first direction from the moisture anti-inflow step;
a second slope having a downward slope such that moisture flows outside from another end in the second direction from the moisture anti-inflow step; and
a bending portion formed by bending downward from another end of the first slope in the first direction.

3. The controlling apparatus of claim 2, wherein a thermal interface material is attached to a rear surface of the moisture blocking cover and the moisture blocking cover is disposed such that the thermal interface material and the heat dissipation fins are in contact with each other.

4. The controlling apparatus of claim 3, wherein the moisture blocking cover increases a flow speed of forcible convection generated from the fan by forming a plurality of channel cross-sections together with the heat dissipation fins.

5. The controlling apparatus of claim 3, wherein masking is applied to an edge area of the rear surface of the moisture blocking cover where the thermal interface material is not attached.

6. The controlling apparatus of claim 2, wherein a side and another side of the drain groove are open such that forcible convection generated from the fan moves to a second direction side from a first direction side through the heat dissipation fins.

7. The controlling apparatus of claim 1, wherein the moisture discharge path includes:
a first moisture discharge path through which moisture is discharged rearward, that is, in a first direction of the drain groove; and
a second moisture discharge path through which moisture is discharged forward, that is, in a second direction of the drain groove.

8. The controlling apparatus of claim 7, wherein the second moisture discharge path is a path through which moisture falling from the moisture blocking cover is guided and discharged to the fan on the basis of a state in which the controlling apparatus is disposed at an angle forward.

9. The controlling apparatus of claim 1, wherein the moisture blocking cover includes a plurality of fixing portions for bolting to the cover top.

10. The controlling apparatus of claim 2, wherein the heat dissipation fins are arranged in parallel with the first direction and are disposed in parallel with a direction perpendicular to the first direction.
